(19) United States
(12) Patent Application Publication
(10) Pub. No.: US 2024/0158941 A1
(43) Pub. Date: May 16, 2024

(54) Gold Plating Bath and Gold Plated Final Finish

(71) Applicant: MacDermid Enthone Inc., Waterbury, CT (US)

(72) Inventors: Roger Bernards, Goshen, CT (US); Emely Abel-Tatis, Bethel, CT (US)

(21) Appl. No.: 18/418,429

(22) Filed: Jan. 22, 2024

Related U.S. Application Data
(63) Continuation of application No. 16/884,314, filed on May 27, 2020.

(51) Int. Cl. C25D 3/48; H05K 3/18; H05K 3/46

(52) U.S. Cl. CPC C25D 3/48; H05K 3/181; H05K 3/4661

(57) ABSTRACT

An autocatalytic gold bath capable of depositing gold from solution onto a substrate, wherein the substrate has one or more metal layers thereon. The autocatalytic gold bath includes (a) a chelator; (b) a gold salt; and (c) a reducing agent, wherein the reducing agent comprises an organic molecule having more than one carbon atom on the organic molecule. A process of plating gold onto the surface of the one or more metal layers on the substrate is also included. The gold plating bath can be used to deposit a final finish to the surface of the one or more metal layers which can be formed in an ENIG, ENEPIG, EPAG, direct gold over copper or gold over silver process.

### FIELD OF THE INVENTION

The present invention relates generally to a final gold surface treatment to increase solderability of a circuit board or IC substrate.

### BACKGROUND OF THE INVENTION

Surface treatments are used to provide improved connectivity. One example of a surface treatment involves gold plating, which is most suitable for final surface treatment of printed circuit boards. It has excellent physical properties such as electrical conductivity, chemical resistance and oxidation resistance of gold as well as solder mounting reliability when mounting electronic components. Nickel plating is typically used as the base metal of electroless gold plating. The surface finish/treatment either protects or forms the connection from the board to a device. Methods in which electroless gold plating is performed after electroless nickel plating is performed on a copper wiring of a printed circuit board include, but not limited to, the following:
a) Electroless Ni/Immersion Au (ENIG);
b) Electroless Ni/Autocatalytic Au (ENAG);
c) Electroless Ni/Immersion Au/Autocatalytic Au (ENIGAG);
d) Electroless Ni/Electroless Pd/Immersion Au (ENEPIG);
e) Direct Au over Cu; and
f) Au over Ag.

As manufacturing and development of electronic components and semiconductor parts continues to advance, improvements in plating techniques are also required. For example, a plating technique may be used to form a circuit pattern on a substrate using a metal such as copper having low electrical resistance when manufacturing a semiconductor package, following by nickel plating, palladium plating, and gold plating to form a joined part.

Electroless nickel/immersion gold plating processes are frequently used for surface treatment for applications that require high reliability in mounting processes of printed circuit boards or electronic parts. For example, in electroless nickel/immersion gold, the immersion gold layer protects the underlying electroless nickel plating from oxidation.

Furthermore, a nickel plated coating film is often used as a barrier film for preventing erosion of a copper circuit caused by solder. Thereafter, a palladium-plated film may be used as a barrier film for preventing diffusion of the nickel plated coating film to a gold plated coating film. Since the gold plated coating film has low electrical resistance and good solder wettability, the gold coated plating film may be applied to the final finish to produce a joined part having excellent joining properties, including solderability and/or wire joining, with a plated coating film comprising a plated coating film made of an underlying metal such as nickel and/or palladium and the gold plated film.

In addition, it is known to subject an underlying metal such as palladium to immersion gold plating to secure adhesion between the plated coating film and the underlying metal. However since the immersion gold plating stops the reaction when the underlying metal is wholly substituted, the immersion gold plating can limit the thickness of the gold plating layer being formed. On the other hand, formation of a thick gold plated coating film may be required for certain portions joined with wire bonding. In order to form the thick gold plated coating film, gold plate processing is performed which requires two steps of subjecting the underlying metal to immersion gold plating processing to secure adhesion and then further subjecting the underlying metal to reduction-type electroless gold plating.

A plate processing operation itself may also be complicated by subjecting the underlying metal such as palladium to immersion gold plate processing and then subjecting the underlying metal to reduction type electroless gold plate processing. The immersion gold plate processing deposits gold using the difference between the oxidation reduction potential of the plated coating film and the underlying metal. The immersion gold plate processing may partially form severe corrosion of the underlying metal. Electroless gold plating baths can suppress the corrosion of the underlying metal, however, there can be issues related to stability of the electroless gold plating bath, resulting in plating deficiencies and unfavorable appearance of the plated gold.

In immersion gold plating, gold is deposited using a difference in redox potential between an underlying nickel layer and a plating bath, so that gold dissolves the nickel thereby corroding the nickel. In addition, diffusion of nickel over the gold film takes place, thereby lowering wire bondability. To avoid this, reduction gold plating may be further performed on the electroless nickel/immersion gold plating films to make a thick gold film thereby suppressing the wire bondability from lowering, but with a problem of costs.

Due in part to the desirability of using lead-free solders, there has been a trend toward the use of Sn—Ag—Cu solder. However, a greater thermal load is needed upon solder bonding when compared with conventional tin-lead eutectic solders, with the attendant problem that bonding characteristics lower. To avoid this problem, a method has been developed that sandwiches a palladium film between the electroless nickel plating layer and the immersion gold plating layer by electroless palladium plating.

Autocatalytic and electroless gold plating baths tend to be unstable, resulting in precipitation of expensive gold salts and gold metal in the plating solution. Thus, it would be desirable to avoid this instability through careful selection of additives used to stabilize the gold plating solution.

U.S. Pat. No. 8,124,174 to Kurosaka et al., the subject matter of which is herein incorporated by reference in its entirety, describes an electroless gold plating bath that includes a water-soluble gold compound, a complexing agent, formaldehyde and/or a formaldehyde bisulfite adduct, and an amine compound. However, the use of formaldehyde and/or a formaldehyde bisulfite adduct has been found to inherently cause instability of the gold plating bath.

Thus, it would be desirable to discover other reducing agents that do not cause instability of the gold plating bath. In other words, it would be desirable to provide a gold plating bath that exhibits improved stability and reduced corrosion, and that can preserve solderability of the deposit.

### SUMMARY OF THE INVENTION

It is an object of the present invention to provide an electroless gold plating bath capable of providing a gold plating layer or film on an underling substrate.

It is another object of the present invention to provide an electroless gold plating bath capable of providing a gold plating layer on an underlying nickel or palladium plated layer.

It is another object of the present invention to provide a gold plating layer that exhibits increased solderability of a final circuit board.

It is still another object of the present invention to provide a gold plating layer that exhibits good conductivity of an electrical contact interface.

It is still another object of the present invention to provide a gold plating bath that provides good stability.

It is still another object of the present invention to provide a gold plating bath that does not precipitate gold or gold salts.

To that end, in one embodiment, the present invention relates generally to a gold plating bath comprising:
A) a chelator;
B) a gold salt; and
C) a reducing agent, wherein the reducing agent comprises an aldehyde and/or an aldehyde bisulfite addition compound.

In another embodiment, the present invention relates generally to a method of metallizing a substrate comprising the steps of:
A) providing a substrate with a metal film deposited thereon;
B) contacting the substrate with a gold plating bath to deposit a gold metal thereon; and
C) plating a sufficient amount of gold to increase the solderability of the metallized substrate.

### DETAILED DESCRIPTION OF THE PREFERRED EMBODIMENTS

The inventors of the present invention have unexpectedly discovered that the use of reducing agents of higher molecular weight and containing additional carbon and/or oxygen atoms attached to the reducing agent can produce a gold plating bath that exhibits greater stability towards plate out and precipitation of gold and gold salts than the previously described formaldehyde and formaldehyde adducts. In one embodiment, the gold plating bath described herein can increase the solderability of a final circuit board. Thus, by using the gold plating bath described herein, a final finish coating can be applied to an underlying metal layer (such as electroless gold or electroless palladium) to preserve solderability.

As used herein, “a,” “an,” and “the” refer to both singular and plural referents unless the context clearly dictates otherwise.

As used herein, the term “about” refers to a measurable value such as a parameter, an amount, a temporal duration, and the like and is meant to include variations of +/−15% or less, preferably variations of +/−10% or less, more preferably variations of +/−5% or less, even more preferably variations of +/−1% or less, and still more preferably variations of +/−0.1% or less of and from the particularly recited value, in so far as such variations are appropriate to perform in the invention described herein. Furthermore, it is also to be understood that the value to which the modifier “about” refers is itself specifically disclosed herein.

As used herein, spatially relative terms, such as “beneath”, “below”, “lower”, “above”, “upper” and the like, are used for ease of description to describe one element or feature's relationship to another element(s) or feature(s) as illustrated in the figures. It is further understood that the terms “front” and “back” are not intended to be limiting and are intended to be interchangeable where appropriate.

As used herein, the terms “comprises” and/or “comprising,” specify the presence of stated features, integers, steps, operations, elements, and/or components, but do not preclude the presence or addition of one or more other features, integers, steps, operations, elements, components, and/or groups thereof.

As used herein the term “substantially-free” or “essentially-free” if not otherwise defined herein for a particular element or compound means that a given element or compound is not detectable by ordinary analytical means that are well known to those skilled in the art of metal plating for bath analysis. Such methods typically include atomic absorption spectrometry, titration, UV-Vis analysis, secondary ion mass spectrometry, and other commonly available analytically methods.

The present invention relates generally to an autocatalytic gold bath for depositing gold or a gold alloy from solution onto a surface through immersion deposition and/or electroless deposition.

In one embodiment, the gold plating bath described herein comprises:
A) a chelator;
B) a gold salt; and
C) a reducing agent, wherein the reducing agent comprises an organic molecule having more than one carbon atom on the organic molecule.

The chelator is typically a compound that is known to be employed as a complexing agent in electroless or autocatalytic gold plating baths. Examples of the chelator or complexing agent include, but are not limited to phosphoric acid, boric acid, Rochelle salt, citric acid, gluconic acid, tartaric acid, lactic acid, malic acid, ethylenediamine, triethanolamine, ethylenediamine tetraacetic acid, nitrilotriacetic acid, diethylenetriamine pentaacetic acid, hydroxyethylethylenediamine triacetic acid, triethylenetetramine hexaacetic acid, 1,3-propanediamine tetraacetic acid, 1,3-diamino-2-hydroxypropane tetraacetic acid, hydroxyethylimino diacetic acid, dihydroxyl glycine, glycol ether diamine tetraacetic acid, dicarboxymethyl glutamic acid, hydroxyethylidene diphosphoric acid, ethylenediamine tetra(methylenephosphoric acid), alkali metal (e.g. sodium or potassium) salts, alkaline earth metal salts and ammonium salts thereof. These complexing agents may be used alone or in combination. In one preferred embodiment, the chelator or complexing agent is ethylenediamine tetraacetic acid or a salt thereof. In another preferred embodiment, the complexing agent comprises one or more of ethylenediamine tetraacetic acid, malic acid, or alkaline earth metal or ammonium salts thereof, even more preferably, the complexing agent may comprise a combination of ethylenediamine tetraacetic acid, sodium salt and sodium malate.

The chelator or complexor is used in the gold plating bath at a concentration of between about 2.0 to about 100 g/L, more preferably about 5 to about 75 g/L, most preferably about 10 to about 50 g/L.

When the concentration is below this range, the deposition rate may slow due to metal dissolving out. In addition, concentrations above this range do not provide any addition benefits to the function of the plating bath.

The gold salt is preferably a water soluble gold salt. Suitable water soluble gold salts include, but are not limited to, gold cyanides, such as potassium gold cyanide, sodium gold cyanide, ammonium gold cyanide and the like, as well as sulfites, sulfates, thiosulfates, thiocyanates, nitrates, methane sulfonates, tetraamine complexes, chlorides, bromides, iodides, hydroxides, oxides, and the like of gold. It is also noted that these water soluble gold salts can be used alone or in combination with each other. In one preferred embodiment, the gold salt is potassium gold cyanide.

The water soluble gold salt is used in the composition at a concentration of between about 0.5 to about 5.0 g/L, more preferably about 0.2 to about 3.0 g/L, and most preferably at a concentration of between about 0.5 and about 1.5 g/L.

The pH of the electroless gold plating bath of the present invention is preferably in the range of about 5 to about 10, more preferably about 6 to about 9, most preferably, about 8.0. When the pH is less than the recited range, the deposition rate can slow, while above the recited range, the plating bath may destabilize. Based thereon, if needed, a pH adjuster can be added to the gold plating solution. Suitable pH adjusters include, but are not limited to, sodium hydroxide, potassium hydroxide, ammonia, sulfuric acid, phosphoric acid, boric acid and other similar compounds that are usable in autocatalytic or electroless gold plating baths.

The electroless gold plating bath is typically maintained at an elevated temperature, such as a temperature within the range of about 60 to about 100° C., more preferably in the range of about 70 to about 95° C., most preferably at a temperature of between about 80 to about 88° C.

The reducing agent usable in the gold plating bath of the invention is characterized in that it is an aldehyde, dialdehyde or ketone, more preferably, bisulfite addition compound of an aldehyde, bialdehyde, or ketone.

In one preferred embodiment the aldehyde contains at least two carbon atoms. For example, the aldehyde may an aliphatic saturated aldehyde such as acetoaldehyde, propionaldehyde, n-butylaldehyde, α-methylvaleraldehyde, β-methylvaleraldehyde, γ-methylvaleraldehyde or the like, an aliphatic dialdehyde such as glyoxal, succindialdehdye glutaraldehyde or the like, an aliphatic unsaturated aldehyde such as croton aldehyde or the like, an aromatic aldehyde such as benzaldehyde, o-nitrobenzaldehyde, m-nitrobenzaldehyde, p-nitrobenzaldehyde, o-tolaldehyde, m-tolaldehyde, p-tolaldehyde, o-hydroxybenzaldehyde, m-hydroxybenzaldehyde, p-hydroxybenzaldehyde, phenylacetoaldehyde or the like, or a sugar having an aldehyde group (—CHO) such as glucose, galactose, mannose, ribose, maltose, lactose or the like. The inventors of the present invention have also found that formaldehyde or bisulfite addition compounds of formaldehyde do not provide a stable bath composition and thus formaldehyde and formaldehyde bisulfite addition compounds are not usable in the baths of the present invention and are specifically excluded from the compositions and processes described herein. That is, aldehydes usable in the practice of the instant invention must contain two or more carbon atoms.

In one embodiment, the aldehyde, bialdehyde, or ketone may also contain additional alcohols, carboxylic acid groups, and/or nitrogen atoms. In a preferred embodiment, the reducing agent described herein is a single or multiple aldehyde group containing at least carbon atoms and further containing additional alcohol groups, carboxylic acid groups, and/or nitrogen groups attached thereto.

Examples of some preferred aldehyde bisulfite addition compounds usable in the present invention include, but are not limited to, p-anisaldehyde bisulfite, sodium salt, 2-methoxy benzaldehyde bisulfite, sodium salt, and indole-3-acetaldehyde bisulfite, sodium salt. Examples of preferred bialdehyde bisulfite addition compounds usable in the present invention include, but are not limited to, oxaldehyde bisulfite, sodium salt, succinaldehyde bisulfite, sodium salt, and glutaraldehyde, sodium salt. One example of a ketone bisulfite addition compound usable in the practice of the instant invention is acetone bisulfite, sodium salt. Other aldehyde, bialdehyde and ketone bisulfite addition compounds would also be usable in the practice of the instant invention and would be known to those skilled in the art.

While the addition compounds described above comprise sodium salts, potassium salts and ammonium salts of bisulfite addition compounds would also be usable in the practice of the invention and be known to those skilled in the art.

The concentration of the reducing agent is typically within the range of about 0.5 to about 25 g/L, more preferably about 1 to about 20 g/L, most preferably within the range of about 3 to about 10 g/L.

In one embodiment, the gold plating bath also comprises an amine Example of suitable amines include, but are not limited to, alkyl amine containing an amino group such as butyl amine, pentyl amine, hexyl amine, heptyl amine, octyl amine, nonyl amine, decyl amine, undecyl amine, dodecyl amine, tridecyl amine, tetradecyl amine, pentadecyl amine, hexadecyl amine, heptadecyl amine, octadecyl amine, nonadecyl amine, or eicodecyl amine. In addition, the compound having an amino group may have a branched structure. Other suitable amines are described, for example, in U.S. Pat. No. 8,124,174 to Kurosaka et al. and in U.S. Pat. No. 8,771,409 to Asakawa et al., the subject matter of each of which is herein incorporated by reference in its entirety. In one embodiment, the amine is selected from the group consisting of ethylenediamine, diethylenetriamine, triethylenetetramine, pentaethylenehexamine, and combinations of one or more of the foregoing.

If used, the amine is used in the plating bath at a concentration of between about 0.1 and about 100 g/L, more preferably at a concentration of between about 0.5 and about 10 g/L.

In one embodiment, the molar ratio between the reducing agent and the amine compound is preferably in the range of about 1:30 to about 3:1, more preferably 1:10 to 1:1.

If desired, the gold plating bath may also contain other suitable additives including, but not limited to surfactants, crystallization modifiers, buffers, flattening agents, thickness controlling agents, antifoaming agents, and other similar compounds.

In one preferred embodiment, the gold plating bath is subjected to mild agitation such as by stirring. In addition, the bath may be subjected to periodic or continuous filtration.

The gold electroplating bath may be periodically or continuously monitored to maintain the concentration of the constituents within the desired range.

As described herein, in one embodiment, the gold plating bath described herein is used to produce a final finish to an underlying metal layer such as in an ENIG, ENEPIG, EPAG, direct gold over copper or gold over silver process.

Thus, the present invention is usable in the printed circuit board industry as a final finish to the metals on the circuit board to preserve solderability. The final finish allows the circuit boards to be successfully soldered with components, especially surface mounted components.

In one embodiment, the present invention is used as a final finish in an electroless nickel immersion gold (ENIG) or electroless nickel electroless platinum immersion gold (ENEPIG) process.

The invention described herein provides an immersion and/or autocatalytic gold bath that exhibits improved stability and reduced plate out as compared with gold plating baths of the prior art.

In another embodiment, the present invention also relates generally to a method of providing a gold final finish on a substrate, the method comprising the steps of:
A) providing a substrate with a metal layer thereon; and
B) contacting the metal layer with a gold plating bath to deposit gold metal thereon, the gold plating bath comprising:
   i) a chelator;
   ii) a gold salt; and
   iii) a reducing agent, wherein the reducing agent comprises an organic molecule having more than one carbon atom on the organic molecule; and

As described herein, the gold plating bath described herein can be used as a final finish over a variety of underlying metals. Based thereon, in one embodiment, the substrate comprises a metal layer, preferably a plating film deposited on the substrate. In one embodiment, the substrate comprises a circuit board or IC substrate with a metal film deposited thereon. The deposited metal film may be EN, ENEP, ENIP, by way of example and not limitation.

The substrate with the metal layer thereon is preferably contacted with the gold plating bath by immersing the substrate in the gold plating bath for a period of time sufficient to achieve the desired thickness. In one embodiment, the desired thickness is a thickness that is sufficient to increase the solderability of metal film stack. In one embodiment, the desired thickness is in the range of about 0.001 to about 40 μm, more preferably about 0.01 to about 10 μm, most preferably about 0.05 to about 1 μm. The plating time is simply the time required to achieve the desired thickness.

In an ENIG plating process, a catalytic electroless nickel plating film is deposited on an underlying substrate by known electroless nickel processes.

When the electroless nickel plating film is deposited on a surface to be plated (e.g. a surface of a copper substrate) through a catalyst, a metal serving as the catalyst includes nickel, cobalt, iron, silver, gold, ruthenium, palladium, platinum or the like, of which palladium is preferred. The deposition amount of the catalyst may be one sufficient for activation to an extent that an electroless nickel film is deposited on the surface to be plated.

In one embodiment, the electroless nickel plating bath comprises a water-soluble nickel salt, a reducing agent and a complexing agent. Suitable water-soluble nickel salts include nickel sulfate and nickel chloride. Suitable reducing agents include hypophosphorous acid such as hypophosphite or sodium hypophosphite, dimethylamine borane, trimethylamine borane, hydrazine or similar compounds. Complexing agents include carboxylic acids such as malic acid, succinic acid, lactic acid, or citric acid, sodium salts thereof, and amino acids such as glycine, alanine, iminodiacetic acid, arginine or glutamic acid. In other embodiment, the electroless nickel bath also contains a sulfur compound.

The electroless nickel plating film formed should preferably have a thickness of from 0.1 to 20 μm, more preferably from 1 to 15 μm. When the thickness is smaller than 0.1 μm, there is concern that wire bondability lowers. Over 20 μm, it takes a long plating time, with the possibility that productivity becomes worsened, thus being disadvantageous in cost.

In an ENEPIG plating process, the catalytic electroless nickel plating film has deposited thereon an electroless palladium plating film.

The electroless palladium plating film can be deposited from various baths, including an immersion type, a reduction type (a formic acid bath, a hypophosphite bath, or a phosphite bath) or other similar type bath. In one embodiment, it is preferred to form a plating film in an electroless palladium plating bath, which is characterized by including, for example, a palladium compound, at least one compound selected from ammonia and amine compounds for use as a complexing agent, at least one hypophosphorous acid compound selected from hypophosphorous acid and hypophosphites for use as a reducing agent, and at least one unsaturated carboxylic acid compound selected from unsaturated carboxylic acids, unsaturated carboxylic anhydrides, unsaturated carboxylic acid salts and unsaturated carboxylic acid derivatives.

The palladium compound may be any of those compounds that are soluble in water and include, for example, palladium chloride, palladium sulfate, palladium acetate, palladium nitrate, tetraamine palladium chloride and the like. The palladium bath may also contain at least one ingredient selected from hypophosphorous acid and hypophosphites as a reducing agent. In addition, at least one of ammonia and an amine compounds may be contained in the composition as a complexing agent. The electroless palladium plating bath may also include at least one unsaturated carboxylic acid compound selected from unsaturated carboxylic acids, unsaturated carboxylic anhydrides, unsaturated carboxylic acid salts, and unsaturated carboxylic acid derivatives.

The electroless palladium plating bath has preferably a pH of from 4 to 10, more preferably from 6 to 8. The thickness of the electroless palladium plating film is preferably in the range from 0.001 to 1.0 μm, more preferably from 0.01 to 0.3 μm. The pH of the solution may be adjusted by adding a suitable pH adjuster.

Unlike a conventional immersion gold plating bath, the electroless gold plating bath of the invention is an electroless gold plating bath of the substitution-reduction type wherein both substitution reaction and reduction reaction proceed in the same plating bath. Since the aldehyde and/or aldehyde bisulfite adduct and the amine compound represented by the general formula (1) or (2) and having a specific type of structure are contained in the gold plating bath, the electroless gold plating bath of the invention allows not only gold to be deposited on an underlying metal by the substitution reaction, but also gold to be further deposited by means of a reducing agent through the initially deposited gold as a catalyst.

The electroless gold plating bath of the invention allows a palladium surface to be activated and gold to be deposited by means of a reducing agent while using the palladium as a catalyst. Gold can be further deposited using the once deposited gold as a catalyst, so that the gold plating film can be thickened on the palladium.

When the electroless gold plating bath of the invention is brought into contact with a palladium plating film, the surface of the palladium plating film can be subjected to electroless gold plating treatment. In this case, a 0.01 to 2 μm thick of gold plating film can be formed in a contact time, for example, of 5 to 60 minutes. The gold plating film can be formed at a deposition rate, for example, of 0.002 to 0.03 pin/minute.

The present invention will now be illustrated with reference to the following non-limiting examples:

### Example 1

Circuit board test parts containing a 25 μm layer of copper were plated in an electroless nickel bath (Affinity 1.0, from MacDermid, Inc.) to deposit Ni/P to a thickness of approximately 5 μm.

The parts were rinsed and submerged into the following gold plating bath operated at 80° C. until a deposit thickness of approximately 0.1 μm was reached:

| | | |
|---|---|---|
| Potassium gold cyanide | 1.2 | g/L |
| Ethylenediaminetetraacetic acid sodium salt | 20 | g/L |
| Glutaraldehyde bisulfite, sodium salt | 5 | g/L |
| Sodium malate | 20 | g/L |
| Balance D.I. water | | |

The pH of the solution was adjusted to pH 8 with either sulfuric acid or potassium hydroxide.

The resulting gold deposit was bright and uniform. Upon inspecting the parts for hyper corrosion of the Ni/P layer, no corrosion was found on any of the features. The gold bath was stable and did not plate out of solution. The amount of nickel dissolved into the bath upon extended use demonstrated that at least some of the gold deposited onto the surface was deposited by autocatalytic reduction from solution and only a portion of the gold deposited was from immersion displacement with nickel.

### Example 2

Circuit board test parts containing a 25 μm of copper were plated in an electroless nickel bath (Affinity 1.0, from MacDermid, Inc.) to deposit Ni/P to a thickness of approximately 5 μm, and a second deposit over the Ni/P was deposited from an electroless palladium bath (Affinity Pd, from MacDermid, Inc.) to a thickness of 0.05 μm. The parts were rinsed and submerged into the following gold plating bath until a deposit thickness of approximately 0.1 μm was reached:

| | | |
|---|---|---|
| Potassium gold cyanide | 1.2 | g/L |
| Ethylenediaminetetraacetic acid sodium salt | 20 | g/L |
| Glutaraldehyde bisulfite, sodium salt | 5 | g/L |
| Sodium malate | 20 | g/L |
| Balance D.I. water | | |

The pH of the solution was adjusted to pH 8 with either sulfuric acid or potassium hydroxide.

The resulting gold deposit was bright and uniform. Upon inspecting the parts for hyper corrosion of the Ni/P layer there was no corrosion found on any of the features. The gold bath was stable and did not plate out of solution.

### Example 3

To the formulation in example 1, 10 g/L of Hydroxylethylethylendiamine was added to the solution. The same parts as in Example 1 were again plated in the gold at 80° C. until a deposit of approximately 0.1 μm was reached. The resulting gold deposit was bright and shiny. Again, no hyper corrosion of the Ni/P layer was evident. The gold bath was stable and did not plate out.

### Comparative Example 1

The same tests were performed using a gold bath that does not contain an aldehyde reducing agent. The bath was an immersion gold bath (Affinity 1.0 from MacDermid, Inc.) that does not have any autocatalytic reduction of the gold. The same parts as in Example 1 were plated at 80° C. until a deposit of approximately 0.1 μm of gold was reached. Upon inspecting the parts, hyper corrosion of the Ni/P layer was observed due to the gold immersion reaction hyper corroding the Ni/P layer.

### Comparative Example 2

A gold bath with the following formulation was prepared and tested for stability.

| | | |
|---|---|---|
| Potassium gold cyanide | 1.2 | g/L |
| Ethylenediaminetetraacetic acid sodium salt | 20 | g/L |
| Formaldehyde bisulfite adduct | 5 | g/L |
| Sodium malate | 20 | g/L |
| Balance D.I. water | | |

The pH of the solution was adjusted to pH 8 with either sulfuric acid or potassium hydroxide.

The bath was maintained at 80° C. 5 hours/day for 5 days. The bath was not stable and showed gold plate out at the bottom of the tank.

As shown in the Examples, plating baths utilizing the reducing agents described herein can be used to produce gold deposits that are more corrosion resistance and increased solderability as compared to plating baths of the prior art. The plating baths described herein also exhibit improved stability and do not plate out.

The electroless gold plating method described herein can be used for gold plating treatment, for example, of wiring circuit mounting portions or terminal portions of printed circuit boards, ceramic substrates, semiconductor substrates, and IC packages.

Finally, it should also be understood that the following claims are intended to cover all of the generic and specific features of the invention described herein and all statements of the scope of the invention that as a matter of language might fall there between.

What is claimed is:

1. (canceled)

2. (canceled)

3. (canceled)

4. (canceled)

5. (canceled)

6. (canceled)

7. (canceled)

8. (canceled)

9. A method of applying a gold final finish on a substrate by autocatalytic gold plating, the method comprising, the steps of:
a) providing a substrate with one or more metal layer thereon; and
b) contacting the substrate with the one or more metal layers with an autocatalytic gold plating bath to deposit gold metal thereon, the autocatalytic gold plating bath comprising:
i) a chelator;
ii) a water soluble gold cyanide salt; and
iii) a reducing agent, wherein the reducing agent comprises a glutaraldehyde bisulfite addition compound;
iv) optionally, an amine; and
v) balance water;
wherein the bath is maintained at a pH in the range of 6 to 8 and a temperature of 80-88° C.;
wherein the bath is at least substantially free of formaldehyde or a bisulfite addition co mound of formaldehyde;
wherein the gold is deposited on the one or more metal layers, wherein the solderability of the one or more metal layers is increased; and
wherein gold salts and gold metal do not precipitate from the gold plating bath when the gold plating bath is operated for at least 5 hours/day for at least 5 days.

10. The method according to claim 9, wherein the one or more metal layers comprise palladium and/or nickel.

11. The method according to claim 9, wherein the gold is plated onto an electroless nickel plated layer over copper features of a semiconductor substrate or printed circuit board.

12. The method according to claim 11, wherein the electroless nickel layer comprises a palladium-plated film over the top of the nickel layer to prevent diffusion of the nickel layer to the gold deposit.

13. The process according to claim 9, wherein the gold plating bath deposits a final finish to the surface of the one or more metal layers, wherein the one or more metal layers are formed in an EMIG, ENEPIG, EPAG, direct gold over copper or gold over silver process.

14. The process according to claim 9, wherein the substrate is a circuit board and gold is deposited as a final finish to the one or more metal layers on the circuit hoard, wherein the deposited gold increases solderability of the one or more metal layers.

15. (canceled)

16. (canceled)

17. (canceled)

18. (canceled)

19. The process according to claim 9, wherein the chelator is selected from the group consisting of one or more of phosphoric acid, boric acid, Rochelle salt, citric acid, gluconic acid, tartaric acid, lactic acid, malic acid, ethylenediamine, triethanolamine, ethylenediamine tetraacetic acid, nitrilotriacetic acid, diethylenetriamine pentaacetic acid, hydroxyethylethylenediamine triacetic acid, triethylenetetramine hexaacetic acid, 1,3-propanediamine tetraacetic acid, 1,3-diamino-2-hydroxypropane tetraacetic acid, hydroxyethylimino diacetic acid, dihydroxyl glycine, glycol ether diamine tetraacetic acid, dicarboxymethyl glutamic acid, hydroxyethylidene diphosphoric acid, ethylenediamine tetra(methylenephosphonic acid), alkali metal salts, alkaline earth metal salts and ammonium salts thereof.

20. The process of claim 19, wherein the chelator comprises one or more of ethylenediamine tetraacetic acid, malic acid, or alkaline earth metal or ammonium salts thereof.

21. The process of claim 20, wherein the chelator consists of ethylenediamine tetraacetic acid, sodium salt and sodium malate.

22. The process of claim 21, wherein the concentration of the chelator is in the range of about 10 to about 50 g/L.

23. The process of claim 12, wherein the gold is deposited on palladium-plated film to a thickness of about 0.01 to about 0.3 μm.
